(19) United States
(12) Patent Application Publication
(10) Pub. No.: US 2022/0406725 A1
(43) Pub. Date: Dec. 22, 2022

(54) GLASS PACKAGE CORE WITH PLANAR STRUCTURES

(71) Applicant: Intel Corporation, Santa Clara, CA (US)

(72) Inventors: Telesphor KAMGAING, Chandler, AZ (US); Veronica STRONG, Hillsboro, OR (US); Neelam PRABHU GAUNKAR, Chandler, AZ (US); Georgios C. DOGIAMIS, Chandler, AZ (US); Aleksandar ALEKSOV, Chandler, AZ (US); Johanna M. SWAN, Scottsdale, AZ (US)

(21) Appl. No.: 17/350,175

(22) Filed: Jun. 17, 2021

(51) Int. Cl. H01L 23/552; H01L 23/15; H01L 23/498; H01L 21/48

(52) U.S. Cl. CPC H01L 23/552; H01L 23/15; H01L 23/49827; H01L 23/49838; H01L 23/49866; H01L 21/486

(57) ABSTRACT

Embodiments described herein may be related to apparatuses, processes, and techniques related to glass interposers or substrates that may be created using a glass etching process to enable highly integrated modules. Planar structures, which may be vertical planar structures, created within the glass interposer may be used to provide shielding for conductive vias in the glass interposer, to increase the signal density within the glass substrate and to reduce cross talk. Other embodiments may be described and/or claimed.

### FIELD

Embodiments of the present disclosure generally relate to the field of semiconductor packaging, and in particular planar structures within semiconductor packaging cores.

### BACKGROUND

Continued growth in virtual machines and cloud computing will continue to increase the demand for high-speed I/O between packages and substrates.

### BRIEF DESCRIPTION OF THE DRAWINGS

FIG. 1 illustrates multiple examples of laser-assisted etching of glass interconnects processes, in accordance with embodiments.

FIG. 2 illustrates a side view of a package having a glass core with multiple planar structures with dies attached to the glass core, in accordance with various embodiments.

FIG. 3 illustrates a side view of a package having a glass core with multiple planar structures with routing features on a surface of the glass core, in accordance with various embodiments.

FIG. 4 illustrates a side view of a package having a glass core with multiple planar structures with routing features on a surface of the glass core with multiple dies attached to both sides of the glass core, in accordance with various embodiments.

FIG. 5 illustrates a illustrates a side view of a package having a glass core with multiple planar structures with routing features on a surface of the glass core with planar structures within a redistribution layer (RDL) to shield the routing features, in accordance with various embodiments.

FIG. 6 illustrates a side view of a package having a glass core with multiple planar structures with routing features on a surface of the glass core and a RDL on the routing features side of the glass core, in accordance with various embodiments.

FIG. 7 illustrates a side view of a package having a glass core with multiple planar structures with routing features on a surface of the glass core and a RDL on a side of the glass core opposite the routing features, in accordance with various embodiments.

FIG. 8 illustrates a side view of a package having a glass core with multiple planar structures with routing features on both surfaces of the glass core, with a conductive via electrically coupling one or more dies on opposite sides of the glass core, in accordance with various embodiments.

FIG. 9 illustrates an example process for creating a planar structure and conductive vias within a glass core, in accordance with various embodiments.

FIG. 10 schematically illustrates a computing device, in accordance with embodiments.

### DETAILED DESCRIPTION

Embodiments described herein may be related to apparatuses, processes, and techniques for fabricating glass substrates that include vias and planes. In embodiments, the glass substrates may be thin glass substrates, and may have fine pitch vias and planes in any shape formed in the substrates. In embodiments, the substrate is used as part of a packaging to enable architectures where dies may be in close proximity with each other. In embodiments, silicon dies may be mounted directly to the glass substrate, which in these embodiments may also be referred to as a glass interposer, to enable fine pitch integration with the silicon dies as well.

Embodiments may include a glass interposer that may be used as a core or an interposer for highly integrated systems in modules. The glass core may include several vias and planes that are formed using laser-assisted etching techniques as described herein. In embodiments, the vias may be separated by vertical planes and/or trench vias for signal isolation. In embodiments, the vias may have high aspect ratios, for example a diameter as small as 5 μm on 100 μm thick substrate. A high via density within the core or the interposer may further enable architectures where dies are assembled on different sides of the glass core or interposer, as described elsewhere herein.

Embodiments may result in packages that have an overall smaller form factor, high-bandwidth density, high signal isolation and limited cross talk, in comparison with legacy packages. In addition, embodiments may facilitate chip disaggregation and re-stitching. Thus, highly integrated modules on a glass core package with vertical planes and/or planar structures may be implemented. These implementations may be particularly useful for client, handheld, wearables and portable devices.

Three-dimensional (3D) heterogeneous integration enables various dies to be in close proximity of each other within a module or on a package substrate. In legacy architectures, an interposer is required to enable dense interconnects between the different dies, where legacy interposers may include silicon as a substrate material. In legacy implementations, liner capacitance associated with doped silicon limits the frequency bandwidth and significantly increases the electrical or signal losses in modules that use silicon as interposers. In legacy implementations, low doped silicon does not suffer from liner capacitance, but exhibits excessive cross talk or coupling between the signals carried in through silicon vias.

Embodiments described herein may be directed to glass interposers that use a glass etching process described herein to enable highly integrated modules. Planar structures, which may be vertical planar structures within a glass substrate, may be created using the glass etching process described herein to increase the density integration within the glass substrate and to reduce cross talk, improve signal integrity, power delivery and EMI.

With respect to the laser-assisted etching process, one or more laser sources followed by wet-etching may be used to create through hole vias or trenches into the glass panel or glass wafer. Using these laser techniques, vias may be created with a small diameter, for example on the order of less than 10 μm, and may be spaced with a pitch on the order of 50 μm or less. Other vias may be created with different diameter sizes. These vias may be later plated or filled to create electrical pathways through the bridge. These techniques may be used to create vias in the glass wafer or panel that have high aspects ratios, for example 10:1, 20:1, 40:1 or 50:1. These techniques may also be used to create vertical planar structures within a glass substrate. Because of the fine pitch of the vias, more signals may be put through the BGA field and the package core at a higher density and may expand the frequency range resulting in higher bandwidth communications. In addition, these techniques may reduce or eliminate impedance mismatch, which in legacy implementations may limit the frequency bandwidth of signals transmitted through the package BGA interface.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

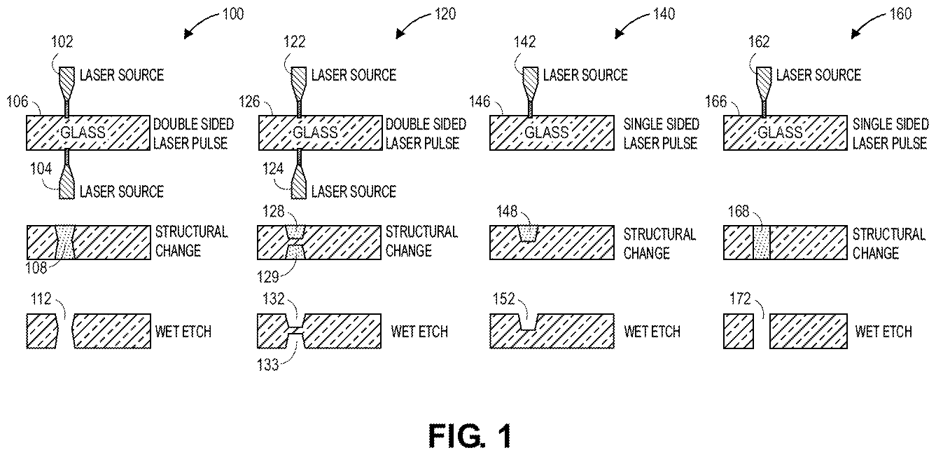

FIG. 1 illustrates multiple examples of laser-assisted etching of glass interconnects processes (which may be referred to as “LEGIT” herein), in accordance with embodiments. One use of the LEGIT technique is to provide an alternative substrate core material to the legacy copper clad laminate (CCL) core used in semiconductor packages used to implement products such as servers, graphics, clients, 5G, and the like. By using laser-assisted etching, crack free, high density via drills, hollow shapes may be formed into a glass substrate. In embodiments, different process parameters may be adjusted to achieve drills of various shapes and depths, thus opening the door for innovative devices, architectures, processes, and designs in glass. Embodiments, such as the bridge discussed herein, may also take advantage of these techniques.

Diagram 100 shows a high level process flow for a through via and blind via (or trench) in a microelectronic package substrate (e.g. glass) using LEGIT to create a through via or a blind via. A resulting volume/shape of glass with laser-induced morphology change that can then be selectively etched to create a trench, a through hole or a void that can be filled with conductive material. A through via 112 is created by laser pulses from two laser sources 102, 104 on opposite sides of a glass wafer 106. As used herein, a through drill and a through via refers to when the drill or the via starts on one side of the glass/substrate and ends on the other side. A blind drill and a blind via refers to when the drill or the via starts on the surface of the substrate and stops partially inside the substrate. In embodiments, the laser pulses from the two laser sources 102, 104 are applied perpendicularly to the glass wafer 106 to induce a morphological change 108, which may also be referred to as a structural change, in the glass that encounters the laser pulses. This morphological change 108 includes changes in the molecular structure of the glass to make it easier to etch out (remove a portion of the glass). In embodiments, a wet etch process may be used.

Diagram 120 shows a high level process flow for a double blind shape. A double blind shape 132, 133 may be created by laser pulses from two laser sources 122, 124, which may be similar to laser sources 102, 104, that are on opposite sides of the glass wafer 126, which may be similar to glass wafer 106. In this example, adjustments may be made in the laser pulse energy and/or the laser pulse exposure time from the two laser sources 122, 124. As a result, morphological changes 128, 129 in the glass 126 may result, with these changes making it easier to etch out portions of the glass. In embodiments, a wet etch process may be used.

Diagram 140 shows a high level process flow for a single-blind shape, which may also be referred to as a trench. In this example, a single laser source 142 delivers a laser pulse to the glass wafer 146 to create a morphological change 148 in the glass 146. As described above, these morphological changes make it easier to etch out a portion of the glass 152. In embodiments, a wet etch process may be used.

Diagram 160 shows a high level process flow for a through via shape. In this example, a single laser source 162 applies a laser pulse to the glass 166 to create a morphological change 168 in the glass 166, with the change making it easier to etch out a portion of the glass 172. As shown here, the laser pulse energy and/or laser pulse exposure time from the laser source 162 has been adjusted to create an etched out portion 172 that extends entirely through the glass 166.

With respect to FIG. 1, although embodiments show laser sources 102, 104, 122, 124, 142, 162 as perpendicular to a surface of the glass 106, 126, 146, 166, in embodiments, the laser sources may be positioned at an angle to the surface of the glass, with pulse energy and/or pulse exposure time variations in order to cause a diagonal via or a trench, or to shape the via, such as 112, 172, for example to make it cylindrical, tapered, or include some other feature. In addition, varying the glass type may also cause different features within a via or a trench as the etching of glass is strongly dependent on the chemical composition of the glass.

In embodiments using the process described with respect to FIG. 1, through hole vias 112, 172 may be created that are less than 10 μm in diameter, and may have an aspect ratio of 40:1 to 50:1. As a result, a far higher density of vias may be placed within the glass and be placed closer to each other at a fine pitch. In embodiments, this pitch may be 50 μm or less. After creating the vias or trenches, a metallization process may be applied in order to create a conductive pathway through the vias or trenches, for example a plated through hole (PTH). Using these techniques, finer pitch vias will result in better signaling, allowing more I/O signals to be put through the glass wafer and to other coupled components such as a substrate.

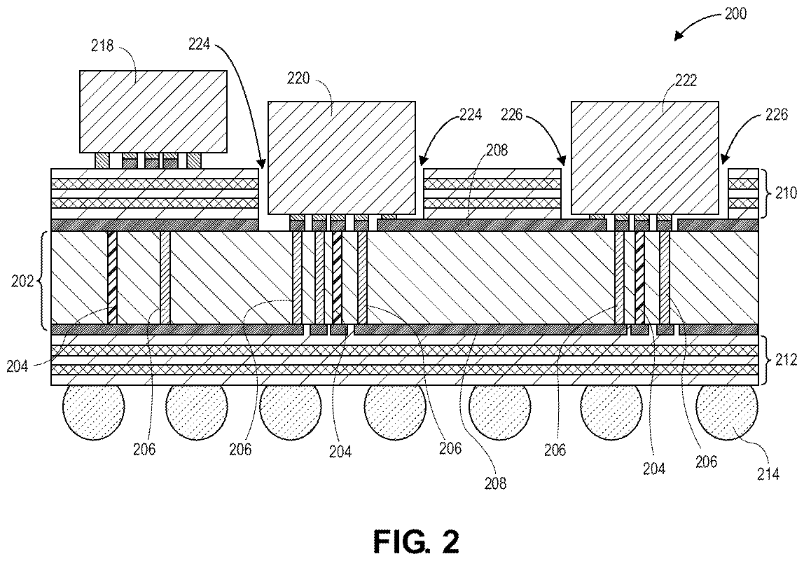

FIG. 2 illustrates a side view of a package having a glass core with multiple planar structures with dies attached to the glass core, in accordance with various embodiments. Package 200 is a side view that has a glass core 202 that includes planes 204 that are created into the glass core 202. In embodiments, the planes 204 extend from a first side to a second side opposite the first side of the glass core 202, and may extend through a width of the glass core 202. In embodiments, the planes 204 may be vertical planes. In embodiments, the planes 204 may be filled with a conductive material to provide electromagnetic interference (EMI) isolation with other electrical features, in particular conductive vias 206, within the glass core 202, discussed in more detail below. In embodiments, the conductive material may include copper, gold, tin, aluminum, or some other suitable conductive material.

The glass core 202 may contain one or more conductive vias 206 to electrically couple the first side and the second side of the glass core 202. In embodiments, one or more of the vias 206 may be located between two planes 204, in order to provide shielding for the vias 206. In embodiments, the planes 204 may be coupled with an electrical ground in the package 200 to facilitate the shielding properties of the planes 204. In embodiments, some of the planes 204 may be used for power delivery to supply power, for example to supply power to one or more dies.

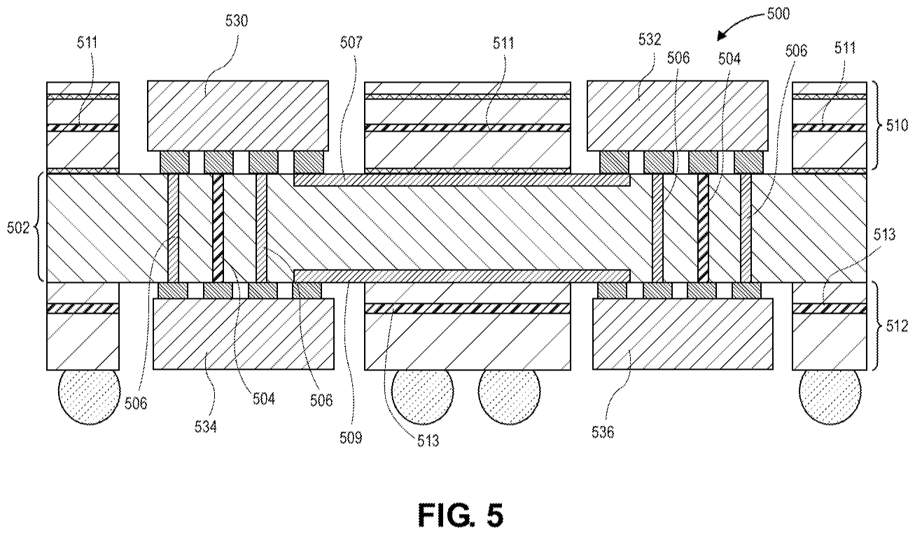

In embodiments, one or more conductive traces 208 may be coupled to a surface of the glass core 202. In embodiments, the conductive traces 208 may be placed into trenches (not shown) on the surface of the glass core 202, so that a top of the conductive traces 208 is at an even level with a surface of the glass core 202. In embodiments, the conductive traces 208 may serve as a redistribution layer, or as interconnects between dies, such as dies 220, 222, that are on a same side or are on opposite sides (shown in FIG. 5) of the glass core 202. In embodiments, the dies 220, 222 may be compute dies, compute die complexes, graphics dies, storage dies, communication dies, and the like.

In embodiments, a first RDL 210 may be coupled with a first side of the glass core 202, and a second RDL 212 may be coupled with the second side of the glass core 202 opposite the first side. The RDL 210, 212 may include multiple layers of metals, where the different layers may be separated by nonconductive dielectric material. These metal layers may serve as redistribution layers for both signaling and power delivery. Electrical features within the RDL 210, 212 may electrically couple with the planes 204 and the conductive vias 206. In embodiments, RDL 212 may include interconnects, such as solder balls 214 on one side of the RDL 212 to electrically and physically couple with a substrate or with some other device (not shown).

In embodiments, one or more dies 218, 220, 222 may be coupled with the glass core 202. Die 218 may be electrically and physically coupled to a surface of the RDL 210 on the first side of the glass core 202. Dies 220, 222 may be electrically and physically coupled with the glass core 202, within cavities 224, 226 in the RDL 210. In embodiments, the dies 220, 222 may be electrically coupled with one or more vias 206 and/or planes 204.

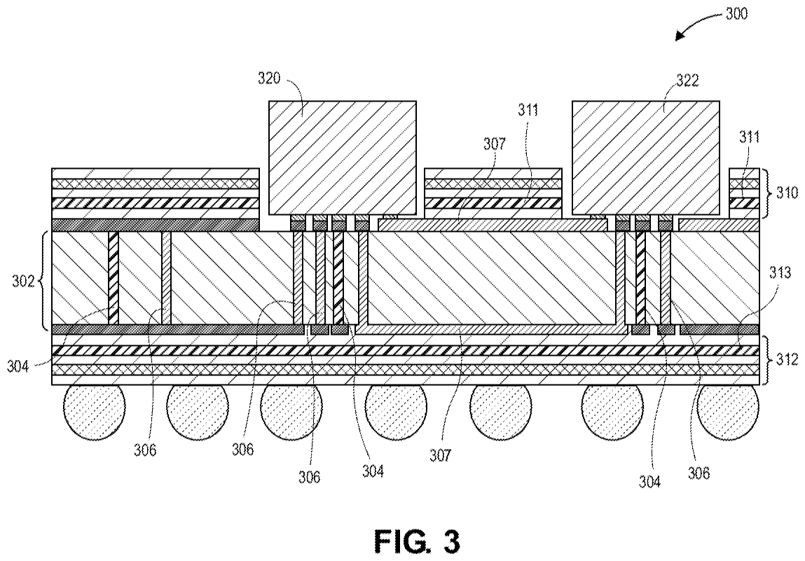

FIG. 3 illustrates a side view of a package having a glass core with multiple planar structures with routing features on a surface of the glass core, in accordance with various embodiments. Package 300, which may be similar to package 200 of FIG. 2, includes a glass core 302, planes 304, conductive vias 306, and RDL 310, 312, which may be similar to glass core 202, planes 204, conductive vias 206, and RDL 210, 212 of FIG. 2.

Package 300 illustrates connection between dies 320, 322 on the same side of the glass core 302. Signals may be routed on the glass core 302, using conductive vias 306, as well through conductive traces 307, which may be similar conductive traces 208 of FIG. 2, to electrically couple the dies 320, 322 on both sides of the glass core 302. In embodiments, horizontal ground planes 311 within RDL 310, and horizontal ground plane 313 within RDL 312 may be used in conjunction with the planes 304 to provide shielding and impedance control.

In embodiments, the RDL 310, 312 may be formed using a semiconductor fabrication process such as chemical vapor deposition (CVD), with spin coating followed by plating. Using these techniques, the dielectric layers of the RDL 310, 312 may be on the order of 100 nanometers (nm) to 5 μm.

In other embodiments, the dielectric layers of the RDL 310, 312 may be formed using a lamination or spin coating that may be used on a typical multilayer organic package substrate. The dielectric layers of the RDL 310, 312 may also be referred to as buildup layers, and may have a thickness on the order of a few micrometers to tens of microns, for example, from 2 μm to 50 μm.

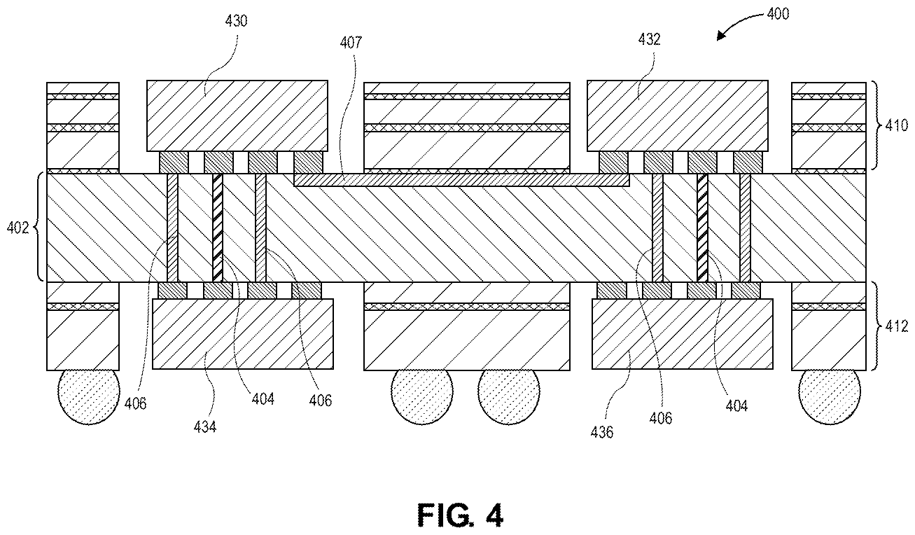

FIG. 4 illustrates a side view of a package having a glass core with multiple planar structures with routing features on a surface of the glass core with multiple dies attached to both sides of the glass core, in accordance with various embodiments. Package 400, which may be similar to package 300 of FIG. 3, includes a glass core 402, planes 404, conductive vias 406, conductive traces 407 and RDL 410, 412, which may be similar to glass core 302, planes 304, conductive vias 306, conductive traces 407, and RDL 310, 312 of FIG. 3.

Dies 430, 432 are physically and electrically coupled with a first side of the glass core 402, physically and electrically coupled with planes 404 and conductive vias 406. In addition, dies 430, 432 are electrically coupled using conductive trace 407. As shown, the conductive trace 407 may be positioned between planes 404, which may provide shielding for the conductive trace 407 and other conductive vias 406 between the conductive planes 404.

As shown, dies 434, 436 are electrically and physically coupled to a second side of the glass core 402 opposite dies 430, 432. Dies 434, 436 are also electrically coupled with conductive vias 406 and planes 404. In embodiments, the planes 404 may be filled with a conductive material, and also coupled with a ground of the package 400 to provide shielding within portions of the package 400. In embodiments, the planes 404 may be used for power delivery, which may result in reduced inductance and low series resistance. In embodiments, the planes 404 may also be used as references for signal lines, in particular when controlling impedance is important.

FIG. 5 illustrates a side view of a package having a glass core with multiple planar structures with routing features on a surface of the glass core with planar structures within a RDL to shield the routing features, in accordance with various embodiments. Package 500 may be similar to package 400 of FIG. 4, and include glass core 502, conductive vias 506, planes 504, high-speed horizontal bus (conductive traces) 507, 509, RDL 510, 512, and horizontal ground planes 511, 513. These may be similar to glass core 402, conductive vias 406, planes 404, conductive traces 407, and RDL 410, 412 of FIG. 4, and horizontal ground planes 311, 313 of FIG. 3.

As shown, all of the dies 530, 532, 534, 536, which may be similar to dies 430, 432, 434, 436 of FIG. 4, are physically and electrically coupled to the glass core 502. Dies 530, 532 may be coupled with a high-speed horizontal bus 507 that is included within a conductive trace, and dies 534, 536 may be coupled with a high-speed horizontal bus 509 that is included within a conductive trace. In embodiments, the horizontal ground planes 511, 513, in addition to the planes 504 surrounding the high-speed horizontal buses 507, 509 may provide shielding during package 500 operation. In embodiments, the planes 504 may also serve as a ground reference for signals on the high-speed horizontal buses 507, 509.

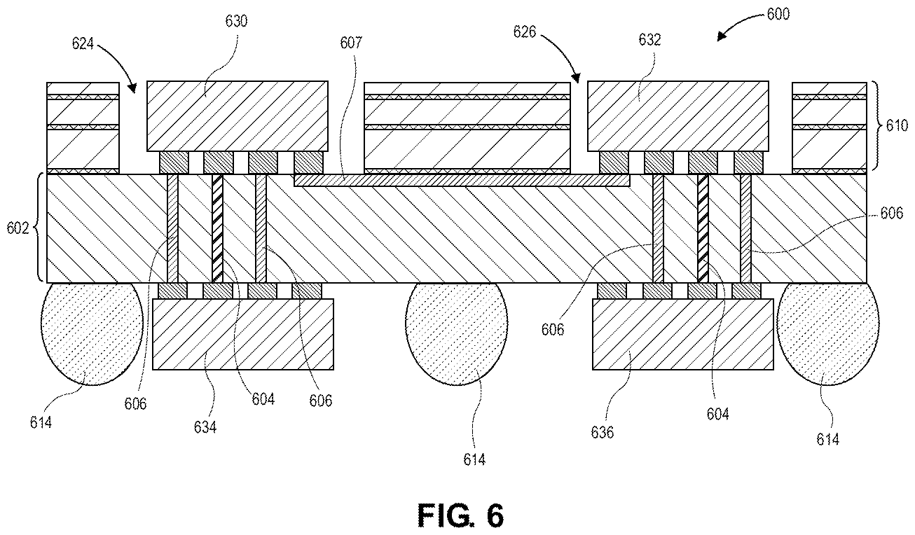

FIG. 6 illustrates a side view of a package having a glass core with multiple planar structures with routing features on a surface of the glass core and a RDL on the routing features side of the glass core, in accordance with various embodiments. Package 600 may be similar to package 500 of FIG. 5, and include glass core 602, conductive vias 606, planes 604, conductive trace 607, and RDL 610. These may be similar to glass core 502, conductive vias 506, planes 504, conductive trace 507, and RDL 510 of FIG. 5.

Package 600 includes dies 630, 632, 634, 636, which may be similar to dies 530, 532, 534, 536 of FIG. 5, that are physically and electrically coupled with the glass core 602. Note that there is only one RDL 610 on a side of the glass core 602 that includes dies 630, 632 that are located within cavities 624, 626, which may be similar to cavities 224, 226 of FIG. 2, within the RDL 610.

On the other side of the glass core 602, solder balls 614 may be placed that allow dies 634, 636 to be coupled to the glass core 602 after the solder balls 614 are attached to a substrate or to another device (not shown). In embodiments, the solder balls 614 are of a sufficient size to not interfere with the operation of the dies 634, 636.

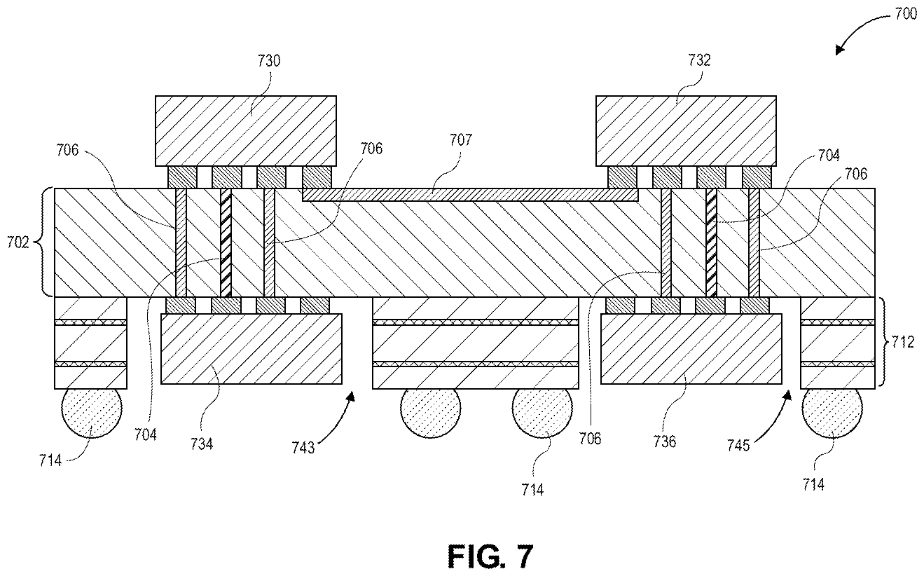

FIG. 7 illustrates a side view of a package having a glass core with multiple planar structures with routing features on a surface of the glass core and a RDL on a side of the glass core opposite the routing features, in accordance with various embodiments. Package 700 may include glass core 702, conductive vias 706, planes 704, conductive trace 707, and RDL 712. These may be similar to glass core 602, conductive vias 606, planes 604, conductive trace 607, and RDL 610 of FIG. 6.

Package 700 includes dies 730, 732, 734, 736, which may be similar to dies 630, 632, 634, 636 of FIG. 6, that are physically and electrically coupled to the glass core 702. Note that there is only one RDL 712 on a side of the glass core 702 that includes dies 734, 736 that are located within cavities 743, 745, respectively, within the RDL 712.

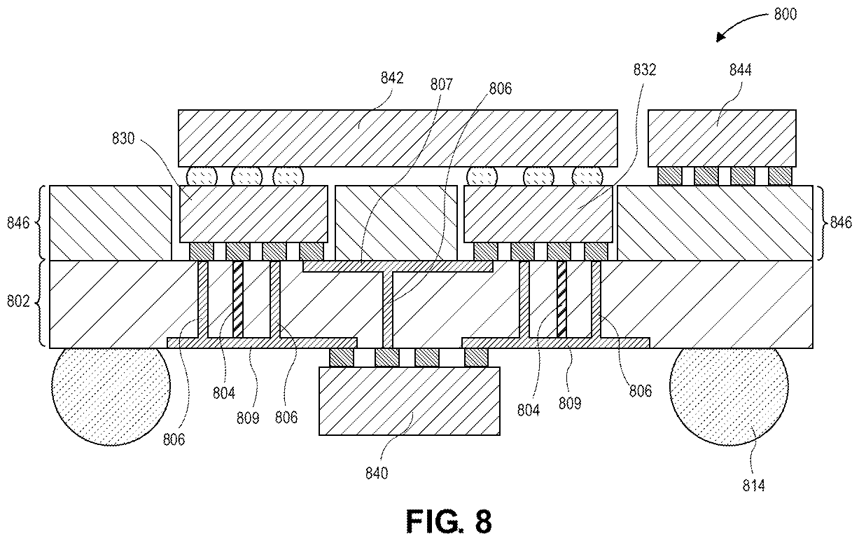

FIG. 8 illustrates a side view of a package having a glass core with multiple planar structures with routing features on both surfaces of the glass core, with a conductive via electrically coupling one or more dies on opposite sides of the glass core, in accordance with various embodiments. Package 800 shows an embodiment that is an extended architecture using stacked dies.

Package 800 may include glass core 802, conductive vias 806, planes 804, and conductive traces 807, 809. These may be similar to glass core 702, conductive vias 706, planes 704, and conductive trace 707 of FIG. 7. Package 800 includes dies 830, 832, 840, 842, which may be similar to dies 730, 732, 734, 736 of FIG. 7.

A molding layer 846 that is coupled to a side of the glass core 802, may have cavities into which dies 830, 832 may be inserted and may be electrically coupled to the glass core 802. In embodiments, the dies 830, 832 may be electrically coupled with the other side of the glass core 802 using conductive vias 806, and conductive traces 809. In embodiments, the dies 830, 832 may be electrically coupled with the die 840 using the conductive traces 809. In embodiments, the dies 830, 832 may be electrically coupled with the die 840 using conductive traces 807 that is coupled with the dies 830, 832, and electrically coupled with die 840 using a conductive via 806 as shown.

In embodiments, a die 842 may be stacked on top of and electrically coupled with the dies 830, 832. In embodiments, the die 842 may be stacked on top of the molding layer 846. In embodiments, another die 844 may be coupled with the molding 846, and electrically coupled with some other die or device (not shown). Solder balls 814, which may be similar to solder balls 714 of FIG. 7, may be used to electrically and physically couple the package 802 a substrate or to another device (not shown). In embodiments, the height of the solder balls 814 is great enough to allow the die 840 to be positioned between the solder balls 814 after assembly and to function normally during the operation of the package 800.

It should be appreciated that the various structures and components shown with respect to FIGS. 2-8 may include multiple examples of embodiments, which may be mixed and/or matched to create a wide variety of 3D heterogeneously integrated packages that include planar structures through glass cores to provide shielding for conductive features within the glass core. It should also be appreciated that when a die is directly coupled with a glass layer, the joint may be a solder joint, or a metal to metal joint. In addition the die and glass may be coupled using highbred bonding techniques.

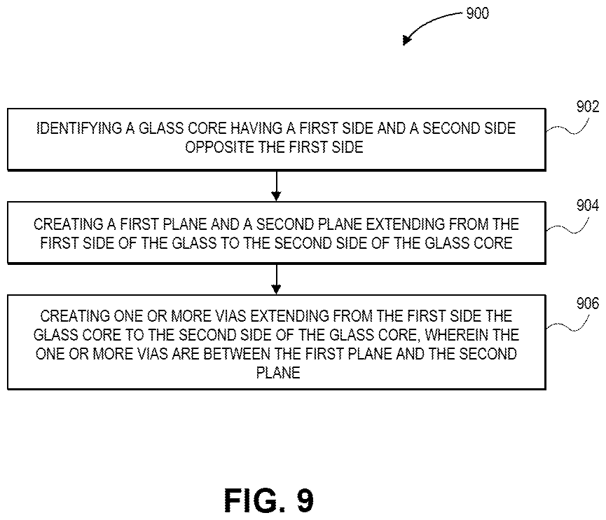

FIG. 9 illustrates an example process for creating a planar structure and conductive vias within a glass core, in accordance with various embodiments. Process 900 may be implemented using the processes, techniques, apparatus, and/or systems described with respect to FIGS. 1-8 herein.

At block 902, the process may include identifying a glass core having a first side and a second side opposite the first side. In embodiments, the glass core may be similar to glass core 106, 126, 146, 166 of FIG. 1, glass core 202 of FIG. 2, 302 of FIG. 3, 402 of FIG. 4, 502 of FIG. 5, 602 of FIG. 6, 702 of FIGS. 7, and 802 of FIG. 8.

At block 904, the process may further include creating a first plane and a second plane extending from the first side of the glass to the second side of the glass core. The process may include one or more techniques as referred to in FIG. 1 above. In embodiments, the first plane and the second plane may be similar to planes 304 of FIG. 3, 404 of FIG. 4, 504 of FIG. 5, 604 of FIG. 6, 704 of FIG. 7, or 804 of FIG. 8.

At block 906, the process may further include creating one or more vias extending from the first side the glass core to the second side of the glass core, wherein the one or more vias are between the first plane and the second plane. The process may include one or more techniques as referred to in FIG. 1 above. In embodiments, the one or more vias may be similar to vias 306 of FIG. 3, 406 of FIG. 4, 506 of FIG. 5, 606 of FIG. 6, 706 of FIG. 7, or 806 of FIG. 8.

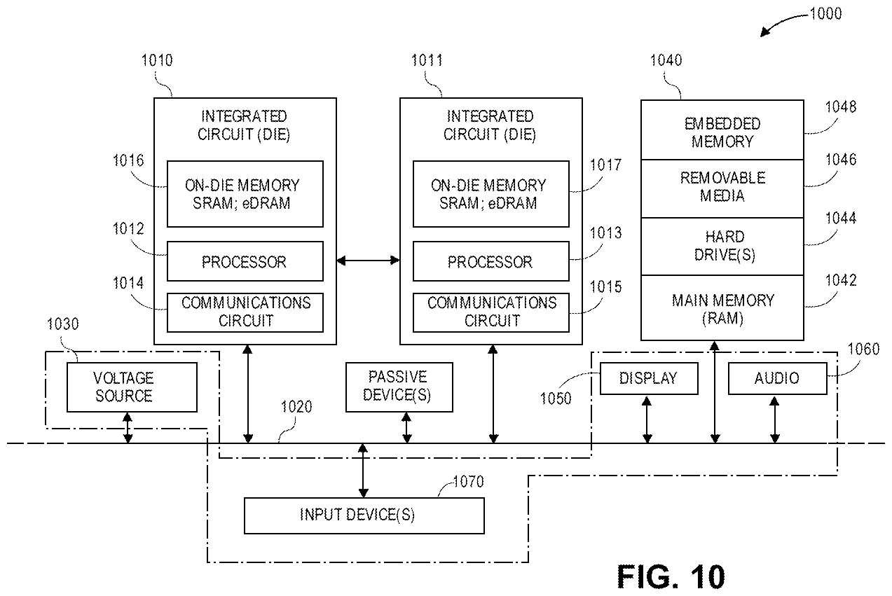

FIG. 10 schematically illustrates a computing device, in accordance with embodiments. The computer system 1000 (also referred to as the electronic system 1000) as depicted can embody all or part of a glass package core with planar structures, according to any of the several disclosed embodiments and their equivalents as set forth in this disclosure. The computer system 1000 may be a mobile device such as a netbook computer. The computer system 1000 may be a mobile device such as a wireless smart phone. The computer system 1000 may be a desktop computer. The computer system 1000 may be a hand-held reader. The computer system 1000 may be a server system. The computer system 1000 may be a supercomputer or high-performance computing system.

In an embodiment, the electronic system 1000 is a computer system that includes a system bus 1020 to electrically couple the various components of the electronic system 1000. The system bus 1020 is a single bus or any combination of busses according to various embodiments. The electronic system 1000 includes a voltage source 1030 that provides power to the integrated circuit 1010. In some embodiments, the voltage source 1030 supplies current to the integrated circuit 1010 through the system bus 1020.

The integrated circuit 1010 is electrically coupled to the system bus 1020 and includes any circuit, or combination of circuits according to an embodiment. In an embodiment, the integrated circuit 1010 includes a processor 1012 that can be of any type. As used herein, the processor 1012 may mean any type of circuit such as, but not limited to, a microprocessor, a microcontroller, a graphics processor, a digital signal processor, or another processor. In an embodiment, the processor 1012 includes, or is coupled with, all or part of a high-speed bridge between a package and a component, as disclosed herein. In an embodiment, SRAM embodiments are found in memory caches of the processor. Other types of circuits that can be included in the integrated circuit 1010 are a custom circuit or an application-specific integrated circuit (ASIC), such as a communications circuit 1014 for use in wireless devices such as cellular telephones, smart phones, pagers, portable computers, two-way radios, and similar electronic systems, or a communications circuit for servers. In an embodiment, the integrated circuit 1010 includes on-die memory 1016 such as static random-access memory (SRAM). In an embodiment, the integrated circuit 1010 includes embedded on-die memory 1016 such as embedded dynamic random-access memory (eDRAM).

In an embodiment, the integrated circuit 1010 is complemented with a subsequent integrated circuit 1011. Useful embodiments include a dual processor 1013 and a dual communications circuit 1015 and dual on-die memory 1017 such as SRAM. In an embodiment, the dual integrated circuit 1010 includes embedded on-die memory 1017 such as eDRAM.

In an embodiment, the electronic system 1000 also includes an external memory 1040 that in turn may include one or more memory elements suitable to the particular application, such as a main memory 1042 in the form of RAM, one or more hard drives 1044, and/or one or more drives that handle removable media 1046, such as diskettes, compact disks (CDs), digital variable disks (DVDs), flash memory drives, and other removable media known in the art. The external memory 1040 may also be embedded memory 1048 such as the first die in a die stack, according to an embodiment.

In an embodiment, the electronic system 1000 also includes a display device 1050, an audio output 1060. In an embodiment, the electronic system 1000 includes an input device such as a controller 1070 that may be a keyboard, mouse, trackball, game controller, microphone, voice-recognition device, or any other input device that inputs information into the electronic system 1000. In an embodiment, an input device 1070 is a camera. In an embodiment, an input device 1070 is a digital sound recorder. In an embodiment, an input device 1070 is a camera and a digital sound recorder.

As shown herein, the integrated circuit 1010 can be implemented in a number of different embodiments, including all or part of a glass package core with planar structures, according to any of the several disclosed embodiments and their equivalents, an electronic system, a computer system, one or more methods of fabricating an integrated circuit, and one or more methods of fabricating an electronic assembly that includes a package substrate implementing all or part of a glass package core with planar structures, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed processes used for a glass package core with planar structures embodiments and their equivalents. A foundation substrate may be included, as represented by the dashed line of FIG. 10. Passive devices may also be included, as is also depicted in FIG. 10.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is an interposer, comprising: a glass core with a first side and a second side opposite the first side; a plurality of planar structures within the glass core extending from the first side of the glass core to the second side of the glass core; and one or more conductive vias extending from the first side of the glass core to the second side of glass core, wherein one of the one or more conductive vias are between a first of the plurality of planar structures and a second of the plurality of planar structures.

Example 2 may include the interposer of example 1, wherein the plurality of planar structures are filled with a conductive material for shielding the one or more conductive vias.

Example 3 may include the interposer example 2, wherein at least some of the plurality of planar structures are electrically coupled with a ground.

Example 4 may include the interposer of example 2, wherein the conductive material includes a selected one or more of: copper, tin, gold, aluminum.

Example 5 may include the interposer of example 1, wherein the plurality of planar structures are substantially parallel to each other.

Example 6 may include the interposer of example 1, further comprising one or more routing structures on the first side of the glass core or the second side of glass core to couple with at least one of the one or more conductive vias.

Example 7 may include the interposer of example 6, wherein the one or more routing structures are recessed into the surface of the first side of the glass core or the second side of the glass core.

Example 8 may include the interposer of example 1, wherein the one or more conductive vias have a 20:1 aspect ratio.

Example 9 may include the interposer of example 1, further comprising a third of the plurality of planar structures and a fourth of the plurality of planar structures within the glass core; and wherein at least one of the one or more conductive vias are between the third of the plurality of planar structures and the fourth of plurality of planar structures.

Example 10 may include the interposer of any one of examples 1-9, wherein one of the planar structures is perpendicular to another of the planar structures.

Example 11 is a package comprising: an interposer, comprising: a glass core with a first side and a second side opposite the first side; a plurality of planar structures within the glass core extending from the first side of the glass core to the second side of the glass core; and one or more conductive vias extending from the first side of the glass core to the second side of glass core, wherein one of the one or more conductive vias are between a first of the plurality of planar structures and a second of the plurality of planar structures, wherein the plurality of planar structures are filled with a conductive material for shielding the one or more conductive vias; and a redistribution layer (RDL) coupled to the first side or the second side of the glass core, the RDL including electrical traces that electrically couple with at least one of the one or more conductive vias.

Example 12 may include the package of example 11, further comprising a die physically coupled with the first side or the second side of the glass core, the die electrically coupled with one of the one or more conductive vias.

Example 13 may include the package of example 12, wherein the die is a first die; and further comprising: a second die physically coupled with the first side or the second side of the glass core on a same side as the first die; and a bus electrically coupling a connector on the first die with a connector on the second die, wherein the bus is on a surface of the glass core.

Example 14 may include the package of example 13, wherein the bus is recessed within the surface of the glass core.

Example 15 may include the package of example 13, further comprising a portion of the RDL between the first die and the second die, wherein the RDL includes a plane filled with conductive material and horizontal to the surface of the glass core, and wherein the bus is between the plane in the RDL filled with conductive material and the surface of the glass core.

Example 16 may include the package of any one of examples 13-15, wherein the bus is electrically coupled with one or more conductive vias.

Example 17 is a method comprising: identifying a glass core having a first side and a second side opposite the first side; creating a first plane and a second plane extending from the first side of the glass to the second side of the glass core; and creating one or more vias extending from the first side the glass core to the second side of the glass core, wherein the one or more vias are between the first plane and the second plane.

Example 18 may include the method of example 17, further comprising inserting conductive material into the first plane, into the second plane, or into the one or more vias.

Example 19 may include the method of example 18, wherein inserting conductive material further comprises a selected one of: conformally plating, or filling.

Example 20 may include the method of any one of examples 18-19, wherein the conductive material includes a selected one or more one of: copper, gold, tin, or aluminum.

What is claimed is:

1. An interposer, comprising:
a glass core with a first side and a second side opposite the first side;
a plurality of planar structures within the glass core extending from the first side of the glass core to the second side of the glass core; and
one or more conductive vias extending from the first side of the glass core to the second side of glass core, wherein one of the one or more conductive vias are between a first of the plurality of planar structures and a second of the plurality of planar structures.

2. The interposer of claim 1, wherein the plurality of planar structures are filled with a conductive material for shielding the one or more conductive vias.

3. The interposer claim 2, wherein at least some of the plurality of planar structures are electrically coupled with a ground.

4. The interposer of claim 2, wherein the conductive material includes a selected one or more of: copper, tin, gold, aluminum.

5. The interposer of claim 1, wherein the plurality of planar structures are substantially parallel to each other.

6. The interposer of claim 1, further comprising one or more routing structures on the first side of the glass core or the second side of glass core to couple with at least one of the one or more conductive vias.

7. The interposer of claim 6, wherein the one or more routing structures are recessed into the surface of the first side of the glass core or the second side of the glass core.

8. The interposer of claim 1, wherein the one or more conductive vias have a 20:1 aspect ratio.

9. The interposer of claim 1, further comprising a third of the plurality of planar structures and a fourth of the plurality of planar structures within the glass core; and
wherein at least one of the one or more conductive vias are between the third of the plurality of planar structures and the fourth of plurality of planar structures.

10. The interposer of claim 1, wherein one of the planar structures is perpendicular to another of the planar structures.

11. A package comprising:
an interposer, comprising:
a glass core with a first side and a second side opposite the first side;
a plurality of planar structures within the glass core extending from the first side of the glass core to the second side of the glass core; and
one or more conductive vias extending from the first side of the glass core to the second side of glass core, wherein one of the one or more conductive vias are between a first of the plurality of planar structures and a second of the plurality of planar structures, wherein the plurality of planar structures are filled with a conductive material for shielding the one or more conductive vias; and
a redistribution layer (RDL) coupled to the first side or the second side of the glass core, the RDL including electrical traces that electrically couple with at least one of the one or more conductive vias.

12. The package of claim 11, further comprising a die physically coupled with the first side or the second side of the glass core, the die electrically coupled with one of the one or more conductive vias.

13. The package of claim 12, wherein the die is a first die; and further comprising:
a second die physically coupled with the first side or the second side of the glass core on a same side as the first die; and
a bus electrically coupling a connector on the first die with a connector on the second die, wherein the bus is on a surface of the glass core.

14. The package of claim 13, wherein the bus is recessed within the surface of the glass core.

15. The package of claim 13, further comprising a portion of the RDL between the first die and the second die, wherein the RDL includes a plane filled with conductive material and horizontal to the surface of the glass core, and wherein the bus is between the plane in the RDL filled with conductive material and the surface of the glass core.

16. The package of claim 13, wherein the bus is electrically coupled with one or more conductive vias.

17. A method comprising:
identifying a glass core having a first side and a second side opposite the first side;
creating a first plane and a second plane extending from the first side of the glass to the second side of the glass core; and
creating one or more vias extending from the first side the glass core to the second side of the glass core, wherein the one or more vias are between the first plane and the second plane.

18. The method of claim 17, further comprising inserting conductive material into the first plane, into the second plane, or into the one or more vias.

19. The method of claim 18, wherein inserting conductive material further comprises a selected one of: conformally plating, or filling.

20. The method of claim 18, wherein the conductive material includes a selected one or more one of: copper, gold, tin, or aluminum.
